(19) United States
(12) Patent Application Publication
(10) Pub. No.: US 2025/0306459 A1
(43) Pub. Date: Oct. 2, 2025

(54) RESIST COMPOSITION AND PATTERN FORMING METHOD

(71) Applicant: Shin-Etsu Chemical Co., Ltd., Tokyo (JP)

(72) Inventors: Masaki Ohashi, Joetsu-shi (JP); Satoshi Kusama, Joetsu-shi (JP); Kousuke Ohyama, Joetsu-shi (JP); Shun Kikuchi, Joetsu-shi (JP)

(73) Assignee: Shin-Etsu Chemical Co., Ltd., Tokyo (JP)

(21) Appl. No.: 19/088,194

(22) Filed: Mar. 24, 2025

(30) Foreign Application Priority Data
Apr. 2, 2024 (JP) 2024-059625

(51) Int. Cl. G03F 7/004; C07F 3/06; G03F 7/00

(52) U.S. Cl. CPC G03F 7/0042; C07F 3/06; G03F 7/70033

(57) ABSTRACT

The resist composition is excellent in sensitivity, resolution, and LWR and is stable and easy to handle in photolithography using a high-energy ray, and a pattern forming method using the resist composition. The resist composition contains a metal complex composed of a metal atom and a ligand having three or more coordinating functional groups.

### CROSS-REFERENCE TO RELATED APPLICATIONS

This non-provisional application claims priority under 35 U.S.C. § 119(a) on Patent Application No. 2024-059625 filed in Japan on Apr. 2, 2024, the entire contents of which are hereby incorporated by reference.

### TECHNICAL FIELD

The present invention relates to a resist composition and a pattern forming method.

### BACKGROUND ART

As the IoT market expands, higher integration, higher speed, and lower power consumption of LSIs are further required, and pattern rules are becoming increasingly finer. In particular, logic devices are driving miniaturization. As the most advanced miniaturization technology, mass production of 10 nm node devices is performed by double patterning, triple patterning, and quadruple patterning of ArF immersion lithography, and 7 nm node devices by next-generation extreme ultraviolet (EUV) lithography using a wavelength of 13.5 nm are being studied.

With the progress of miniaturization, image blurring due to acid diffusion has become a problem (Non-Patent Document 1). In order to ensure resolution in a fine pattern of the generation of a processing dimension of 45 nm or later, it has been proposed that it is important not only to improve the dissolution contrast that has been conventionally proposed but also to control acid diffusion (Non-Patent Document 2). However, since a chemically amplified resist composition increases the sensitivity and the contrast by acid diffusion, when the acid diffusion is suppressed to the utmost limit by lowering the post-exposure bake (PEB) temperature or shortening the PEB time, the sensitivity and the contrast are remarkably lowered.

It is effective to suppress acid diffusion by adding an acid generator that generates a bulky acid. Therefore, it has been proposed to copolymerize an onium salt acid generator with a polymerizable olefin into a polymer. However, it is considered that, in pattern formation of a resist film of the generation of a processing dimension of 16 nm or later, a pattern cannot be formed with a chemically amplified resist composition from the viewpoint of acid diffusion, and development of a non-chemically amplified resist composition is desired.

Examples of a material for the non-chemically amplified resist composition include polymethyl methacrylate (PMMA). PMMA is a positive resist material in which the main chain is cut by an electron beam (EB) or EUV irradiation, and the solubility in an organic solvent developer is improved as the molecular weight is reduced, but PMMA does not have a ring structure, and therefore has disadvantages of low etching resistance and a large amount of outgas during exposure.

Hydrogensilsesquioxane (HSQ) is a material for a negative resist composition that becomes insoluble in an alkaline developer by crosslinking due to a condensation reaction of silanol generated by an EB or EUV irradiation. Chlorine-substituted calixarenes also function as materials for negative resist compositions. Since these materials have a small molecular size before crosslinking and do not cause blurring due to acid diffusion, the materials have small edge roughness and very high resolution, and are used as pattern transfer materials to show the resolution limit of an exposure apparatus. However, these materials have insufficient sensitivity and require further improvement.

A factor that makes development of materials for EUV lithography difficult is a small number of photons in EUV exposure. The energy of an EUV ray is much higher compared with ArF excimer laser light, and the number of photons in EUV exposure is 1/14 of that in ArF exposure. Furthermore, a dimension of a pattern formed by EUV exposure is less than or equal to half of that of a pattern formed by ArF exposure. For this reason, the EUV exposure is easily affected by a variation in the number of photons. A variation in the number of photons in a radiation light region having a very short wavelength is shot noise of a physical phenomenon, and this effect cannot be eliminated. Therefore, so-called stochastics has attracted attention. Although the effect of shot noise cannot be eliminated, how to reduce this effect has been discussed. A phenomenon has been observed in which not only critical dimension uniformity (CDU) and line width roughness (LWR) increase due to the effect of shot noise, but also a hole is blocked with a probability of one in several millions. When the hole is blocked, a current failure occurs and a transistor does not operate, which adversely affects the performance of an entire device.

As a method for reducing the effect of shot noise on the resist side, an inorganic resist composition having an element having high EUV light absorption as a core has been proposed (Patent Document 1). However, although the inorganic resist composition has relatively high sensitivity, the inorganic resist composition is not yet sufficient, and has many problems such as insufficient solubility in a solvent for the resist composition, storage stability, and defects.

Non-Patent Document 3 proposes a negative resist composition using a tin compound. This is a non-chemically amplified resist composition containing a tin element having high EUV light absorption as a principal component, and although stochastics is improved and sensitivity and resolution are greatly improved, there is a problem in stability, and there is a problem in that the performance varies due to degradation during storage of the resist composition or a delay (time elapsed after PEB until development (post-PEB delay (PPD)) subsequent to PEB.

### CITATION LIST

Patent Document 1: JP-A 2015-108781
Non-Patent Document 1: SPIE Vol. 5039 p1 (2003)
Non-Patent Document 2: SPIE Vol. 6520 p65203L-1 (2007)
Non-Patent Document 3: SPIE Vol. 9051 p90511B-1 (2014)

### SUMMARY OF THE INVENTION

The present invention has been made in view of the above circumstances, and an object of the present invention is to provide a resist composition that is excellent in sensitivity, resolution, and LWR, stable, and easy to handle in photolithography using a high-energy ray, particularly, EB lithography and EUV lithography, and a pattern forming method using the resist composition.

As a result of intensive studies to achieve the above-described object, the present inventors have found that a resist composition containing, as a principal component, a metal complex composed of a metal atom and a ligand having three or more coordinating functional groups has high sensitivity, exhibits excellent resolving power and LWR, provides a resist film having excellent stability, and is extremely effective for precise fine processing, and have completed the present invention.

That is, the present invention provides a resist composition and a pattern forming method which are described below.

1. A resist composition containing a metal complex composed of a metal atom and a ligand having three or more coordinating functional groups.

2. The resist composition according to 1, wherein the metal is zinc.

3. The resist composition according to 1 or 2, wherein the ligand having three or more coordinating functional groups has the following formula (1a) or (1b):

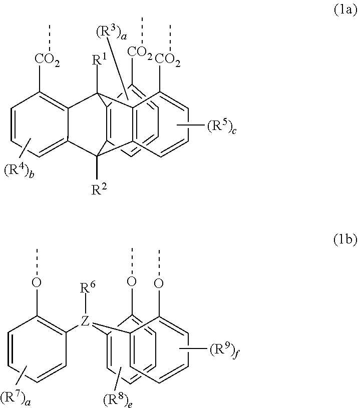

wherein, a, b, and c are each independently 0, 1, 2, or 3, d, e, and f are each independently 0, 1, 2, 3, or 4,
R¹ and R² are each independently a hydrogen atom, a hydroxy group, a halogen atom, or a C₁ to C₂₀ hydrocarbyl group that may have a hetero atom,
R³, R⁴, and R⁵ are each independently a C₁ to C₂₀ hydrocarbyl group that may have a hetero atom,
Z is a carbon atom or a silicon atom,
R⁶ is a hydrogen atom, a hydroxy group, a halogen atom, or a C₁ to C₂₀ hydrocarbyl group that may have a hetero atom,
R⁷, R⁸, and R⁹ are each independently a C₁ to C₂₀ hydrocarbyl group that may have a hetero atom, and
broken lines represent bonds with a metal atom.

4. A pattern forming method including the steps of:
forming a resist film on a substrate using the resist composition according to any one of 1 to 3;
exposing the resist film to a high-energy ray; and
developing the exposed resist film to form a resist pattern.

5. The pattern forming method according to 4, wherein the high-energy ray is an EB or an EUV ray.

### Advantageous Effects of the Invention

A resist composition according to the present invention has both high sensitivity and high resolution, is excellent in LWR, and has good stability particularly in EB lithography and EUV lithography, and therefore is very useful in fine pattern forming.

### DETAILED DESCRIPTION OF THE INVENTION

### [Resist Composition]

A resist composition according to the present invention contains a metal complex composed of a metal atom and a ligand having three or more coordinating functional groups.

### [Metal Complex]

The metal complex has the ligand having three or more coordinating functional groups. The coordinating functional groups rigidly fix the metal atom and stabilize the complex. Therefore, the temporal stability during storage of the resist composition and stability in a delay subsequent to PEB are improved. That is, performance degradation due to PPD is improved. Specific examples of the coordinating functional groups include an amino group, a carboxyl group, a hydroxy group, a thiol group, a cyano group, a carbonyl group, and a phosphino group.

Specific examples of the ligand include triamine, tetramine, triimine, porphyrin, triphosphine, and tetraphosphine.

In the resist composition according to the present invention, a particularly preferred example of the ligand is a ligand having the following formula (1a) or (1b).

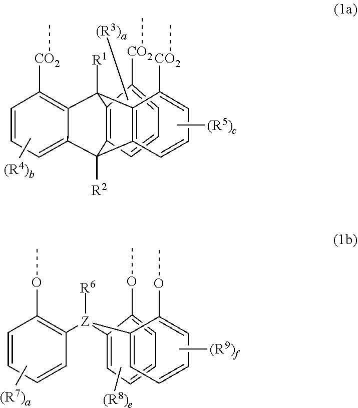

In the formulas (1a) and (1b), a, b, and c are each independently 0, 1, 2, or 3. d, e, and f are each independently 0, 1, 2, 3, or 4. R¹ and R² are each independently a hydrogen atom, a hydroxy group, a halogen atom, or a C₁ to C₂₀ hydrocarbyl group that may have a hetero atom. R³, R⁴, and R⁵ are each independently a C₁ to C₂₀ hydrocarbyl group that may have a hetero atom. Z is a carbon atom or a silicon atom. R⁶ is a hydrogen atom, a hydroxy group, a halogen atom, or a C₁ to C₂₀ hydrocarbyl group that may have a hetero atom. R⁷, R⁸, and R⁹ are each independently a C₁ to C₂₀ hydrocarbyl group that may have a hetero atom. Broken lines represent bonds with a metal atom.

The C₁ to C₂₀ hydrocarbyl groups of R¹ to R⁹ may be saturated or unsaturated, and may be linear, branched, or cyclic. Specific examples of the hydrocarbyl groups include C₁ to C₂₀ alkyl groups, such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃ to C₂₀ cyclic saturated hydrocarbyl groups, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; C₂ to C₂₀ alkenyl groups, such as a vinyl group and a 2-propenyl group; C₆ to C₂₀ aryl groups, such as a phenyl group or a naphthyl group, and a group obtained by combining these. Some or all of hydrogen atoms of the hydrocarbyl groups may be substituted with a group containing a hetero atom such as an oxygen atom, a sulfur atom, a nitrogen atom, or a halogen atom, and one or more of —CH₂— of the hydrocarbyl group may be substituted with a group containing a hetero atom such as an oxygen atom, a sulfur atom, or a nitrogen atom, and as a result, the hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic anhydride (—C(═O)—O—C(═O)—), or the like.

Since the ligand having the formula (1a) or (1b) has an extremely rigid structure, the metal complex having the ligand has greatly improved stability.

The metal element contained in the metal complex is not particularly limited, but is preferably an element that is highly efficient at absorbing an EUV ray. Examples of the element include cobalt (Co), nickel (Ni), copper (Cu), zinc (Zn), aluminum (Al), silver (Ag), indium (In), tin (Sn), antimony (Sb), tellurium (Te), and platinum (Pt). Zinc is particularly preferable in consideration of synthesis, handling, availability of raw materials, and the like. Since zinc highly efficient at absorbing an EUV ray, it can be said that it is very efficient to apply a zinc complex to EUV lithography.

Examples of the metal complex include, but are not limited to, those shown below.

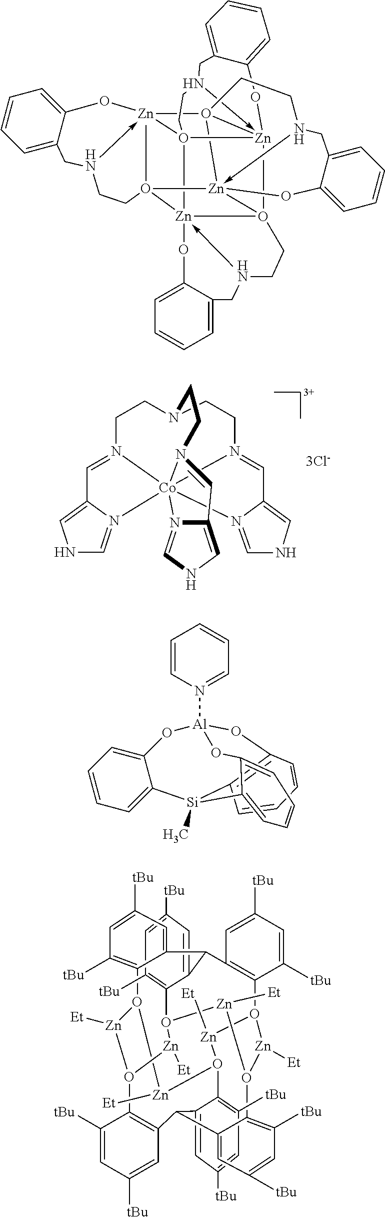

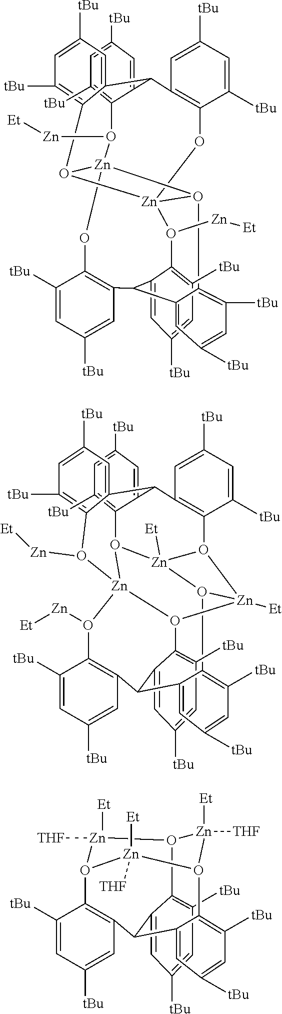

(In the formulas, tBu is a tert-butyl group. THF is tetrahydrofuran.)

Specific examples of the zinc complex having a triptycene ligand include compounds having the composition formula [Zn₁₀(μ₄—O)₄(μ₃—H₂O)₃(L)₄] described in Inorganic Chemistry 2022, 61, 3649-3654. Here, L is a ligand having the following formula (2).

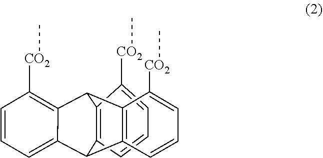

(In the formula, broken lines represent bonds with a metal atom.)

The metal complex may be used singly or in combination of two or more kinds of metal complexes.

### [Organic Solvent]

The resist composition according to the present invention contains an organic solvent. The organic solvent is not particularly limited as long as the organic solvent can dissolve the metal complex and form a film. Examples of the organic solvent include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol mono-tert-butyl ether acetate; lactones such as γ-butyrolactone; carboxylic acids such as acetic acid and propionic acid; aromatics such as toluene, xylene, cresol, anisole, and benztrifluoride; and a mixed solvent thereof.

The amount of the organic solvent is preferably 200 to 20,000 parts by weight and more preferably 500 to 15000 parts by weight per 100 parts by weight of the metal complex.

It is presumed that, in the resist composition according to the present invention, development resistance in an exposed portion and an unexposed portion varies due to photolysis of the metal complex as the principal component and subsequent aggregation or crosslinking reaction between partially broken clusters, and contrast appears. Since this reaction is not a catalytic reaction, the resist composition according to the present invention functions as a non-chemically amplified resist composition. Therefore, a chemically amplified resist composition containing a conventional multicomponent polymer as a principal component can be resolved even in a fine region where pattern formation is difficult. In particular, in EUV lithography, since a zinc atom has high EUV light absorbing power, stochastics is improved, and a resist composition excellent in sensitivity and LWR is obtained. In addition, since the metal complex is thermally stable because a rigid three-dimensional structure is formed by the ligand having three or more coordinating functional groups, the metal complex is also excellent in storage stability. Furthermore, there is no significant change in performance over time after PEB.

### [Photoacid Generator]

The resist composition according to the present invention may contain a photoacid generator as another component other than the metal complex and the organic solvent. By using the photoacid generator, an effect of generating an acid in an exposed portion and promoting crosslinking reaction of a zinc compound can be expected. The photoacid generator is not particularly limited as long as the photoacid generator generates an acid by irradiation with a high-energy ray, and a known photoacid generator can be used as a photoacid generator for a conventional chemically amplified resist composition. In particular, a photoacid generator that generates a sulfonic acid, an imidic acid, or a methidic acid is preferable. Suitable examples of the photoacid generator include sulfonium salts, iodonium salts, sulfonyldiazomethane, N-sulfonyloxyimide, and oxime-O-sulfonate and acid generators. Specific examples of the photoacid generator include those described in paragraphs [0122] to [0142] of JP-A 2008-111103 and those described in paragraphs [0127] of JP-A 2022-163697.

In a case where the resist composition according to the present invention contains the photoacid generator, the amount of the photoacid generator is preferably 0.01 to 20 wt % based on the total amount of all solids. In the present invention, the solids are a generic term for components other than the solvent among all components of the resist composition. The photoacid generator may be used singly or in combination of two or more kinds thereof.

### [Radical Scavenger]

The resist composition according to the present invention may contain a radical scavenger as another component. By adding the radical scavenger, it is possible to control a photoreaction during photolithography to adjust the sensitivity.

As the radical scavenger, hindered phenols, quinones, hindered amines, thiol compounds, and the like can be used. Specific examples of the hindered phenols include dibutylhydroxytoluene and 2,2′-methylenebis(4-methyl-6-tert-butylphenol). Specific examples of the quinones include 4-methoxyphenol(methoquinone) and hydroquinone. Specific examples of the hindered amines include 2,2,6,6-tetramethylpiperidine and 2,2,6,6-tetramethylpiperidine-N-oxy radical. Specific examples of the thiols include dodecanethiol and hexadecanethiol.

In a case where the resist composition according to the present invention contains the radical scavenger, the amount of the radical scavenger is preferably 0.01 to 10 wt % based on the total amount of all the solids. The radical scavenger may be used singly or in combination of two or more kinds thereof.

### [Surfactant]

The resist composition according to the present invention may contain a surfactant as another component. As the surfactant, those described in JP-A 2010-215608 and JP-A 2011-16746 can be referred to. Among those described above, FC-4430 (manufactured by 3M Company), Surflon® S-381 (manufactured by AGC Seimi Chemical Co., Ltd.), Olfin® E1004 (manufactured by Nissin Chemical Industry Co., Ltd.), KH-20 and KH-30 (manufactured by AGC Seimi Chemical Co., Ltd.), an oxetane ring-opening polymer having the following formula (surf-1), and the like are preferable.

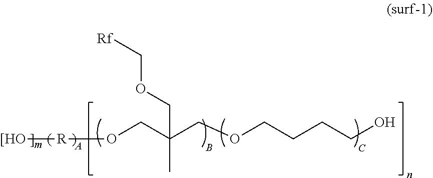

In the formula (surf-1), R is a C₂ to C₅ di- to tetra-valent aliphatic group. Examples of the aliphatic group include a divalent group such as an ethylene group, a 1,4-butylene group, a 1,2-propylene group, a 2,2-dimethyl-1,3-propylene group, and a 1,5-pentylene group, and examples of the trivalent or tetravalent group include the following groups.

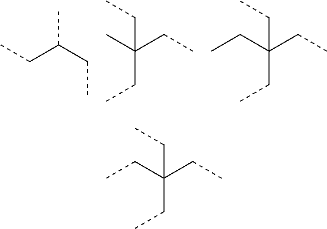

(In the formulas, broken lines are bonds, and the groups are partial structures derived from glycerol, trimethylolethane, trimethylolpropane, and pentaerythritol.)

Among them, a 1,4-butylene group, a 2,2-dimethyl-1,3-propylene group, and the like are preferable.

Rf is a trifluoromethyl group or a pentafluoroethyl group, preferably a trifluoromethyl group. m is an integer of 0 to 3, n is an integer of 1 to 4, and the sum of n and m is a valence of R and an integer of 2 to 4. A is 1. B is an integer of 2 to 25, preferably an integer of 4 to 20. C is an integer of 0 to 10, preferably 0 or 1. In addition, each constituent unit in the formula (surf-1) does not define the arrangement thereof, and may be combined in blocks or randomly combined. The production of a partially fluorinated oxetane ring-opening polymerization-based surfactant is described in detail in U.S. Pat. No. 5,650,483 and the like.

In a case where the resist composition according to the present invention contains the surfactant, the amount of the surfactant is preferably 0.001 to 20 parts by weight and more preferably 0.1 to 10 parts by weight per 100 parts by weight of the metal complex. The surfactant may be used singly or in combination of two or more kinds thereof.

### [Pattern Forming Method]

In a case where the resist composition according to the present invention is used for manufacturing various integrated circuits, a known lithography technique can be applied. For example, examples of a pattern forming method include a method including a step of forming a resist film on a substrate using the above-described resist composition, a step of exposing the resist film to a high-energy ray, and a step of developing the exposed resist film.

First, the resist composition according to the present invention is applied onto a substrate for manufacturing an integrated circuit (Si, SiO₂, SiN, SiON, TiN, WSi, BPSG, SOG, organic antireflection film, or the like) or a substrate for manufacturing a mask circuit (Cr, CrO, CrON, MoSi₂, SiO₂, or the like) by an appropriate application method such as spin coating, roll coating, flow coating, dip coating, spray coating, or doctor coating so as to obtain a coating film having a thickness of 0.01 μm to 2 μm. This is heated on a hot plate. The resist film is formed by heating preferably at 60° C. to 200° C. for 10 seconds to 30 minutes, more preferably at 80° C. to 180° C. for 30 seconds to 20 minutes.

Next, the resist film is exposed using a high-energy ray. Examples of the high-energy ray include an ultraviolet ray, a far ultraviolet ray, an EB, EUV light having a wavelength of 3 nm to 15 nm, an X-ray, a soft X-ray, excimer laser light, a γ-ray, and synchrotron radiation. In a case where an ultraviolet ray, a far ultraviolet ray, an EUV ray, an X-ray, a soft X-ray, excimer laser light, a γ-ray, synchrotron radiation, or the like is used as the high-energy ray, irradiation is performed directly or using a mask for forming a target pattern such that the exposure amount is preferably about 1 mJ/cm² to 200 mJ/cm², more preferably about 10 mJ/cm² to 150 mJ/cm². When an EB is used as the high-energy ray, lithography is performed directly or using a mask for forming a target pattern with an exposure amount of preferably about 0.1 μC/cm² to 5000 μC/cm², more preferably about 0.5 μC/cm² to 4000 μC/cm². The resist composition according to the present invention is particularly suitable for fine patterning with an EB or an EUV ray among high-energy rays.

PEB may be performed to accelerate or complete the reaction after photolysis. When the PEB is performed, the PEB is preferably performed on a hot plate or in an oven after exposure under conditions of preferably 30° C. to 200° C. for 10 seconds to 30 minutes, more preferably 60° C. to 180° C. for 30 seconds to 20 minutes.

A development method performed after the exposure or after the PEB may be either wet development or dry development. In the case of the wet development, alkaline development or development using an organic solvent can be applied, but in a case that a pattern is to be formed with the resist composition according to the present invention, the development using the organic solvent is preferable. The wet development is preferably performed on the exposed resist film for 3 seconds to 3 minutes, more preferably for 5 seconds to 2 minutes, by a conventional method such as a dip method, a puddle method, or a spray method such that a target pattern is formed. Since the resist composition according to the present invention is of a negative type, a portion irradiated with light is insolubilized in the developer, and an unexposed portion is dissolved.

Examples of the organic solvent used as the developer include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, cyclohexyl acetate, butyl formate, isobutyl formate, pentyl formate, isopentyl formate, methyl valerate, methyl pentenate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used singly or in combination of two or more kinds thereof.

After the development, rinsing may be performed as necessary. A rinse solution is preferably a solvent that is mixed with the developer and does not dissolve the resist film. As the solvent, a C₃ to C₁₀ alcohol, a C₈ to C₁₂ ether compound, a C₆ to C₁₂ alkane, a C₆ to C₁₂ alkene, a C₆ to C₁₂ alkyne, and an aromatic solvent are preferably used.

Specific examples of the C₃ to C₁₀ alcohol include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Specific examples of the C₈ to C₁₂ ether compound include di-n-butyl ether, diisobutyl ether, di-sec-butyl ether, di-n-pentyl ether, diisopentyl ether, di-sec-pentyl ether, di-tert-pentyl ether, and di-n-hexyl ether.

Specific examples of the C₆ to C₁₂ alkane include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Specific examples of the C₆ to C₁₂ alkene include hexene, heptene, octene, cyclohexene, methylcyclohexene, dimethylcyclohexene, cycloheptene, and cyclooctene. Specific examples of the C₆ to C₁₂ alkyne include hexyne, heptyne, and octyne.

Specific examples of the aromatic solvent include toluene, xylene, ethylbenzene, isopropylbenzene, tert-butylbenzene, and mesitylene.

By performing the rinsing, it is possible to reduce the occurrence of collapse and defects of the resist pattern. The rinsing is not necessarily required, and the amount of solvent used can be reduced by not performing the rinsing.

Dry development is also applicable as the development method in the pattern forming method according to the present invention. The dry development is development in which either an exposed portion or an unexposed portion is removed by a gas etching process without using a developer. In the case of the present invention, a desired pattern can be formed by removing an unexposed portion with an etching gas. For the dry etching, a gas containing nitrogen for dilution, helium, argon, carbon dioxide, carbon monoxide, or the like is preferably used as a gas containing oxygen, hydrogen, ammonia, halogen, or the like.

### EXAMPLES

The present invention is specifically described below with reference to Examples and Comparative Examples, but the present invention is not limited to the following Examples.

Zinc complexes used in Examples have the following formulas (M-1) to (M-3).

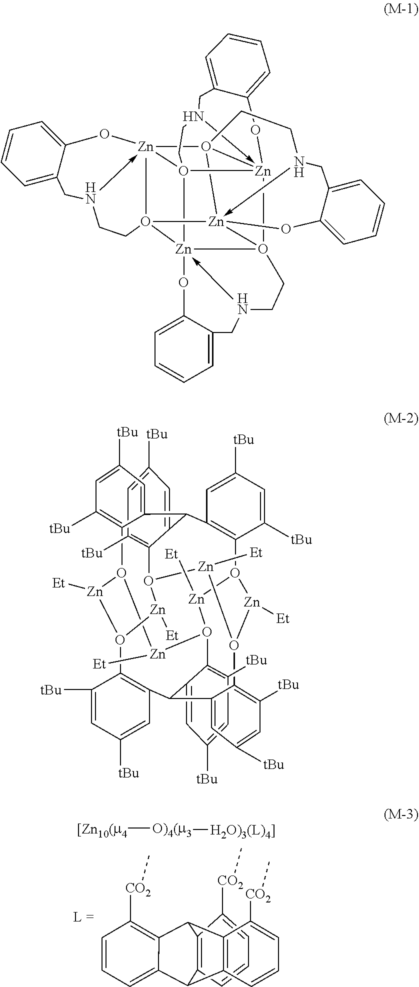

The zinc complex having the formula (M-1) was synthesized with reference to Journal of Materials Chemistry C, 2024, 12, 1683. The zinc complex having the formula (M-2) was synthesized with reference to Inorganic Chemistry 2001, 40, 1029-1036. The zinc complex having the formula (M-3) was synthesized with reference to Inorganic Chemistry 2022, 61, 3649-3654.

### [1] Preparation of Resist Composition

### Examples 1-1 to 1-5 and Comparative Example 1-1

Each component having the composition shown in Table 1 below was dissolved in a solvent, and the resulting solution was filtered through a 0.2-μm Teflon® filter to prepare resist compositions R-1 to R-5 according to the present invention and a resist composition CR-1 for comparison.

TABLE 1

| | | Resist | Component A | Component B | Component C | Solvent |
|---|---|---|---|---|---|---|
| | | composition | (pbw) | (pbw) | (pbw) | (pbw) |
| Example | 1-1 | R-1 | M-1 (20.0) | — | — | Anisole (1000) |
| | 1-2 | R-2 | M-2 (26.3) | — | — | Anisole (1000) |
| | 1-3 | R-3 | M-3 (21.6) | — | — | Anisole (1000) |
| | 1-4 | R-4 | M-2 (26.3) | P-1 (19) | — | Anisole (1000) |
| | 1-5 | R-5 | M-2 (26.3) | — | Sc-1 (0.01) | Anisole (1000) |
| Comparative | 1-1 | CR-1 | CM-1 (20) | — | — | Anisole (1000) |
| Example | | | | | | |

In Table 1, component A is a metal complex, component B is a photoacid generator, and component C is a radical scavenger. The structures of the zinc complexes (M-1) to (M-3) used as component A are as described above. Details of components B and C are as follows.
P-1: Triphenylsulfonium tosylate
Sc-1: Dibutylhydroxytoluene

In Table 1, CM-1 (tin compound) used in Comparative Example was synthesized according to Angewandte Chemie, International Edition (2017), 56 (34), 10140-10144. The structure of CM-1 is as follows.

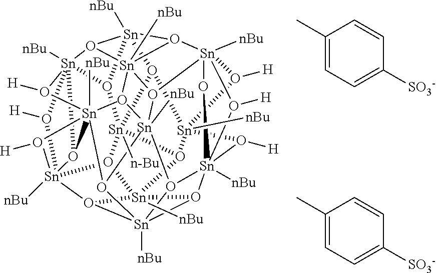

### [2] Eb Lithography Evaluation

### Examples 2-1 to 2-5 and Comparative Example 2-1

Each resist composition (R-1 to R-5 and CR-1) was spin-coated on a Si substrate formed with an antireflection film DUV-42 manufactured by Nissan Chemical Corporation and having a film thickness of 60 nm, and was prebaked at 100° C. for 60 seconds using a hot plate to prepare a resist film having a film thickness of 40 nm. The resist film was exposed using an EB lithography apparatus (ELS-F125, acceleration voltage 125 kV) manufactured by ELIONIX INC., PEB was performed on a hot plate at temperature described in Table 2 for 60 seconds, and development was performed using 2-heptanone as a developer for 30 seconds to form a pattern. As a result, a negative line-and-space (LS) pattern having a space width of 20 nm and a pitch of 40 nm was obtained. For the obtained LS pattern, sensitivity, LWR, and limit resolution were evaluated according to the following methods. The results are shown in Table 2.

### [Sensitivity Evaluation]

The LS pattern was observed with an electron microscope to obtain an optimum exposure amount Eop (μC/cm²) at which the LS pattern having a space width of 20 nm and a pitch of 40 nm was obtained, and the optimum exposure amount Eop was defined as the sensitivity.

### [LWR Evaluation]

Dimensions of 10 places in the longitudinal direction of the space width in the LS pattern obtained by irradiation with the optimum exposure amount were measured with CD-SEM (CG-5000) manufactured by Hitachi High-Tech Co., Ltd., and from the results, a value (36) 3 times the standard deviation (a) was obtained and defined as the LWR. As this value is smaller is, a pattern having a smaller roughness and a more uniform space width can be obtained.

### [Limit Resolution Evaluation]

A limit line width (nm) that can be resolved when a pattern is formed by gradually increasing the exposure amount from the optimum exposure amount was obtained using a length measuring SEM (CG-6300) manufactured by Hitachi High-Tech Co., Ltd., and this limit line width was defined as the limit resolution (nm). The smaller this value is, the more excellent the limit resolution is and a finer pattern can be formed.

### [Evaluation of Post-Exposure Delay Stability]

After exposure with the optimum exposure amount, PEB and development were performed under the above-described conditions. In this case, a wafer (PPD0h) subjected to development without a post-PEB delay to form a pattern and a wafer (PPD6h) subjected to development after a post-PEB delay of 6 hours to form a pattern were prepared. The line widths of these wafers were obtained using the length measuring SEM (CG-6300) manufactured by Hitachi High-Tech Co., Ltd., and changes (ΔPPD) in the line widths (CD) due to post-exposure delay were obtained. The results are shown in Table 2.

TABLE 2

| | | | | | | Limited | PPD 0 h | PPD 6 h | ΔPPD |
|---|---|---|---|---|---|---|---|---|---|
| | | Resist | PEB | EoP | LWR | resolution | CD | CD | CD |
| | | composition | (° C.) | (μC/cm²) | (nm) | (nm) | (nm) | (nm) | (nm) |
| Example | 2-1 | R-1 | 150 | 3000 | 3.4 | 13.8 | 20.2 | 20.6 | 0.4 |
| | 2-2 | R-2 | 150 | 2600 | 3.1 | 13.0 | 20.1 | 21.7 | 0.6 |
| | 2-3 | R-3 | 150 | 3200 | 3.2 | 12.8 | 20.4 | 20.6 | 0.2 |
| | 2-4 | R-4 | 150 | 2400 | 3.6 | 14.0 | 20.0 | 20.7 | 0.7 |
| | 2-5 | R-5 | 150 | 2800 | 3.3 | 12.6 | 19.8 | 20.2 | 0.4 |
| Comparative | 2-1 | CR-1 | 170 | 3200 | 4.7 | 18.6 | 20.1 | 25.2 | 5.1 |
| Example | | | | | | | | | |

From the results shown in Table 2, it was found that the resist composition according to the present invention is excellent in LWR and limit resolution in negative pattern formation by organic solvent development using EB lithography. Furthermore, it was confirmed that the change in CD was small even in the post-exposure delay, and the resist composition was stable even after the pattern formation. In addition, the resist composition according to the present invention contains zinc atoms having high EUV light absorbing power at a high density, and thus is expected to have considerably high sensitivity in EUV lithography.

### [3] Evaluation of Storage Stability

### Examples 3-1 to 3-5 and Comparative Example 3-1

When each of the resist compositions R-1 to R-5 and CR-1 was left for a specific period under normal temperature (20±5° C.) conditions, whether or not precipitation occurred was visually confirmed. In this case, the resist compositions that could be stored without precipitation occurring for 6 months or longer are shown by “0”, and the resist composition in which precipitation occurred in less than 6 months is shown by “x”. The results are shown in Table 3.

TABLE 3

| | | Resist | Storage |
|---|---|---|---|
| | | composition | stability |
| Example | 3-1 | R-1 | ○ |
| | 3-2 | R-2 | ○ |
| | 3-3 | R-3 | ○ |
| | 3-4 | R-4 | ○ |
| | 3-5 | R-5 | ○ |
| Comparative | 3-1 | CR-1 | x |
| Example | | | |

From the results shown in Table 3, it was shown that the resist composition according to the present invention has excellent storage stability and are easy to handle.

Japanese Patent Application No. 2024-059625 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a metal complex composed of a metal atom and a ligand having three or more coordinating functional groups.

2. The resist composition according to claim 1, wherein the metal is zinc.

3. The resist composition according to claim 1, wherein the ligand having three or more coordinating functional groups has the following formula (1a) or (1b), 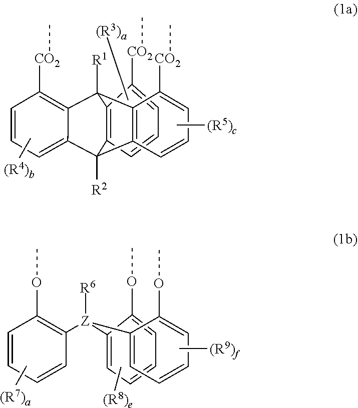
wherein a, b, and c are each independently 0, 1, 2, or 3, d, e, and f are each independently 0, 1, 2, 3, or 4,
R¹ and R² are each independently a hydrogen atom, a hydroxy group, a halogen atom, or a C₁ to C₂₀ hydrocarbyl group that may have a hetero atom,
R³, R⁴, and R⁵ are each independently a C₁ to C₂₀ hydrocarbyl group that may have a hetero atom,
Z is a carbon atom or a silicon atom,
R⁶ is a hydrogen atom, a hydroxy group, a halogen atom, or a C₁ to C₂₀ hydrocarbyl group that may have a hetero atom,
R⁷, R⁸, and R⁹ are each independently a C₁ to C₂₀ hydrocarbyl group that may have a hetero atom, and
broken lines represent bonds with a metal atom.

4. A pattern forming method comprising the steps of:
forming a resist film on a substrate using the resist composition according to claim 1;
exposing the resist film to a high-energy ray; and
developing the exposed resist film to form a resist pattern.

5. The pattern forming method according to claim 4, wherein the high-energy ray is an electron beam or an extreme ultraviolet ray.
